(19) United States
(12) Patent Application Publication
(10) Pub. No.: US 2013/0070435 A1
(43) Pub. Date: Mar. 21, 2013

(54) POWER CONNECTOR AND MOTHERBOARD USING THE SAME

(71) Applicants: YU-MEI LI, Shenzhen City (CN); HSIAO-YUAN NIU, Tu-Cheng (TW); HUI LI, Shenzhen City (CN)

(72) Inventors: YU-MEI LI, Shenzhen City (CN); HSIAO-YUAN NIU, Tu-Cheng (TW); HUI LI, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD, Shenzhen City (CN)

(21) Appl. No.: 13/313,025

(22) Filed: Dec. 7, 2011

(30) Foreign Application Priority Data
Sep. 16, 2011 (CN) 201110275549.8

(51) Int. Cl. H05K 7/00; H01R 12/71

(52) U.S. Cl. 361/760; 439/78

(57) ABSTRACT

A power connector for mounting on a circuit board is provided. The power connector includes a case and several sets of pins. A set of pins includes several pins. Each one of one set of pins includes an embedded end, a median portion, and a distal end, where the embedded end protrudes from one side of the case, the median portion is angled from the embedded end; and the distal end is angled from the media portion and fixed to the circuit board. A part of the power connector case projects outside an edge of the circuit board.

### BACKGROUND

1. Technical Field

The present disclosure relates to power connectors and motherboards using the power connectors.

2. Description of Related Art

Motherboards are common in computers. A miniature motherboard takes up less space in a computer housing, which facilitates the slim design of the computer housing.

### BRIEF DESCRIPTION OF THE DRAWINGS

The components of the drawings are not necessarily drawn to scale, the emphasis instead being placed upon clearly illustrating the principles of the present disclosure. Moreover, in the drawings, like reference numerals designate corresponding parts throughout several views.

FIG. 1 is an isometric view of a motherboard with a power connector connected thereon, in accordance with an exemplary embodiment.

FIG. 2 is similar to FIG. 1, but viewing the motherboard from another perspective.

FIG. 3 is an isometric view of the motherboard of FIG. 1, showing the power connector is separated from the motherboard.

### DETAILED DESCRIPTION

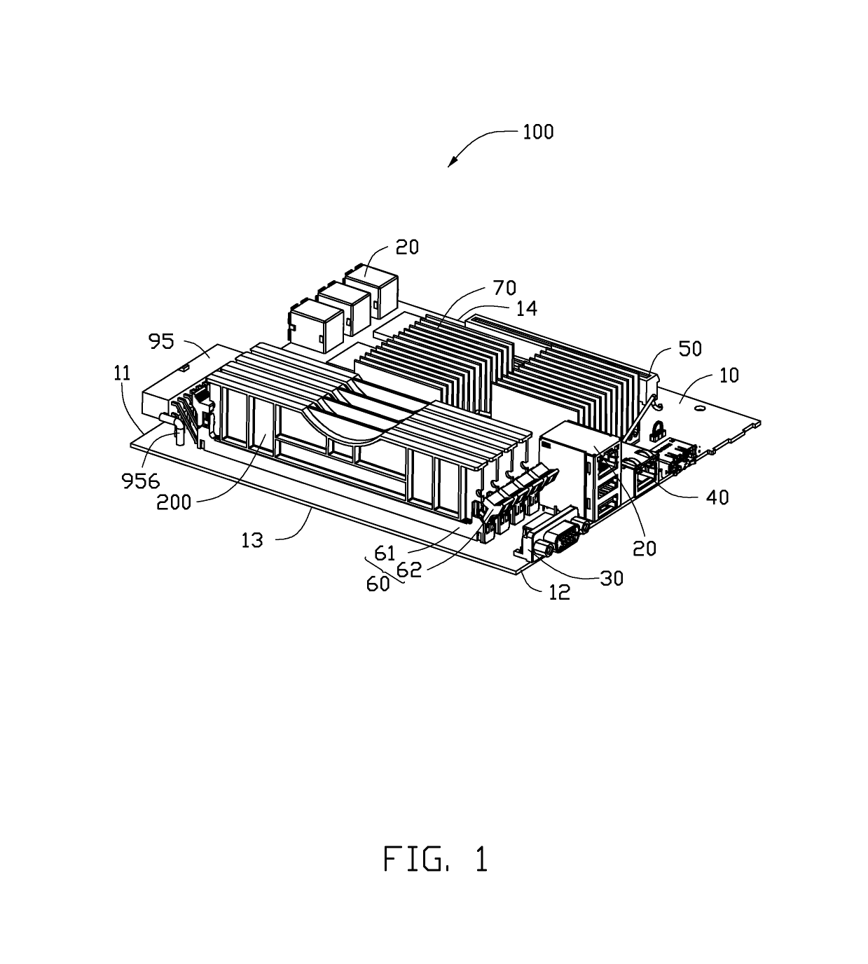

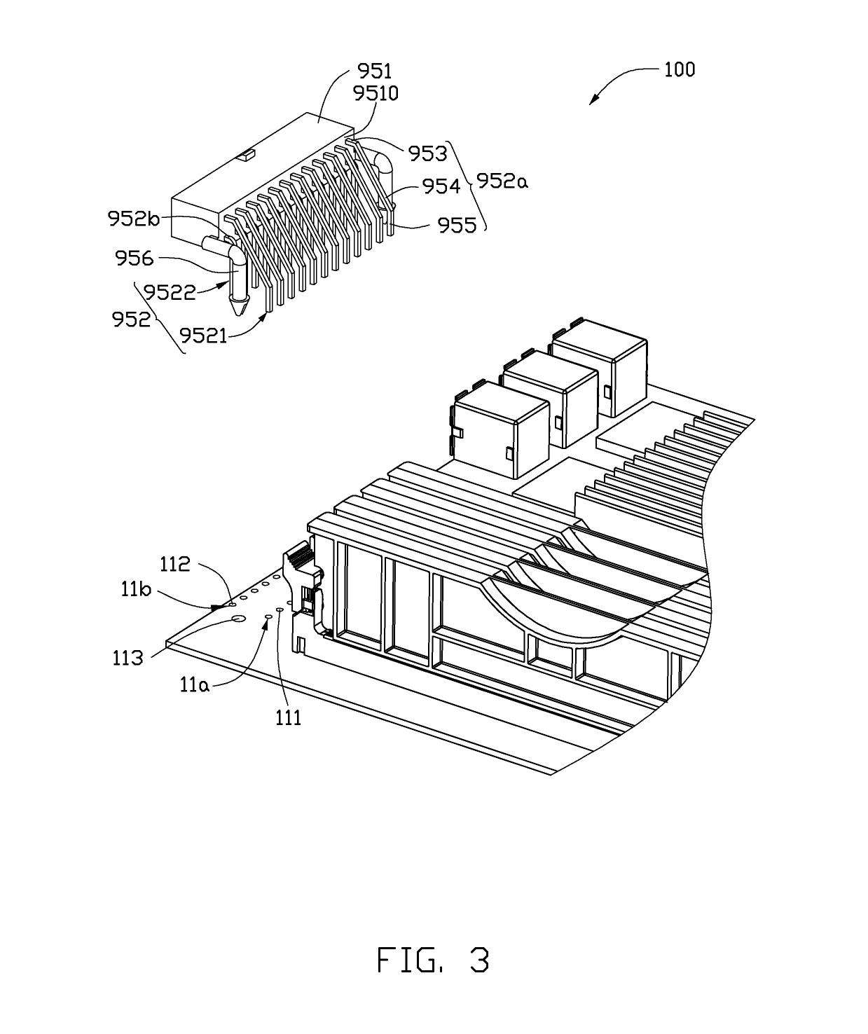

Referring to FIGS. 1-3, a motherboard 100 includes a circuit board 10, four universal serial bus (USB) connectors 20, a data output port 30, an I/O connector 40, a data connector 50 to connect to a hard disk drive, four memory slots 60 for receiving memories 200, two central processing units (CPUs, not shown), two heat sinks 70 arranged on the two CPUs for dissipating heat, and a power connector 95 to connect to a power supply (not shown).

The circuit board 10 is a sheet including a first side 11, a second side 12 opposite the first side 11, a third side 13 between the sides 11 and 12, and a fourth side 14 opposite to the side 13. In this embodiment, the circuit board 10 is a rectangular sheet, the first side 11 is parallel to the second side 12, the third side 13 is parallel to the fourth side 14, and the first side 11 is perpendicular to the third side 14. Three of the four USB connectors 20 are arranged in a line along the first side 11, and electrically connected to the circuit board 10. The fourth USB connector 20, the data output connector 30, and the I/O connector 40 are arranged along the second side 12 and electrically connected to the circuit board 10. The data connector 50 is arranged beside and parallel to the fourth side 14, and electrically connected to the circuit board 10.

The four memory slots 60 are arranged adjacent to and parallel to each other, with their lengthwise direction parallel to the third side 13. Each memory slot 60 includes a receiving slot 61 for receiving a memory 200 and two locking members 62 rotatably connected to two ends of the receiving slot 61. When the two locking members 62 of a memory slot 60 are pulled back to an unlocking state, a memory 200 can be inserted into or removed from the receiving slot 61. When the two locking members 62 are rotated up to a latching position and engage the memory 200, the memory 200 is locked in the receiving slot 61.

The two CPUs are mounted between a memory slot 60 close to the fourth side 14 and the data connector 50.

The power connector 95 is arranged on the circuit board 10 beside the first side 11 and close to the four memory slots 60. The power connector 95 includes a case 951 and a pin group 952. The pin group 952 includes a first set of pins 9521 and a second set of pins 9522. Each set of pins 9521, 9522 includes several pins protruding from the case 951 and arranged at equal intervals. The second set of pins 9522 is beneath the first set of pins 9521 and is spaced a certain distance from the first set of pins 9521.

The first set of pins 9521 includes several first pins 952a. Each first pin 952a includes an embedded end 953, a median portion 954 angled from the embedded end 953, and a distal end 955 angled from the median portion 954. The embedded end 953 of each first pin 952a protrudes from a back side 9510 of the case 951. The distal portion 955 of each first pin 952a is to be connected to the circuit board 10.

In this embodiment, the back side 9510 of the case 951 is vertical, the embedded end 953 of each first pin 952a perpendicularly protrudes from the back side 9510, and the distal portion 955 of each first pin 952a is perpendicular to the embedded end 953 and parallel to the back side 9510. The median portions of all the first pins 952a form an incline. When the two locking members 62 of a memory slot 60 are rotated to an unlatching position, the nearer one of the two locking members 62 may rest on the incline.

The power connector 95 further includes two orientation rods 956, flanking the sets of pins 9521 and 9522, to be inserted into orientation holes 113 in the circuit board 10, to locate the power connector 95 on the circuit board 10. The orientation poles 956 may be made of plastic materials.

A first row of holes 11a and a second row of holes 11b are arranged in the circuit board 10. The first row of holes 11a includes several through holes 111 into which the distal ends 955 of the first pins 952a are inserted. The second row of holes 11b includes several through holes 112 into which the pins of the second set of pins 9522 are inserted.

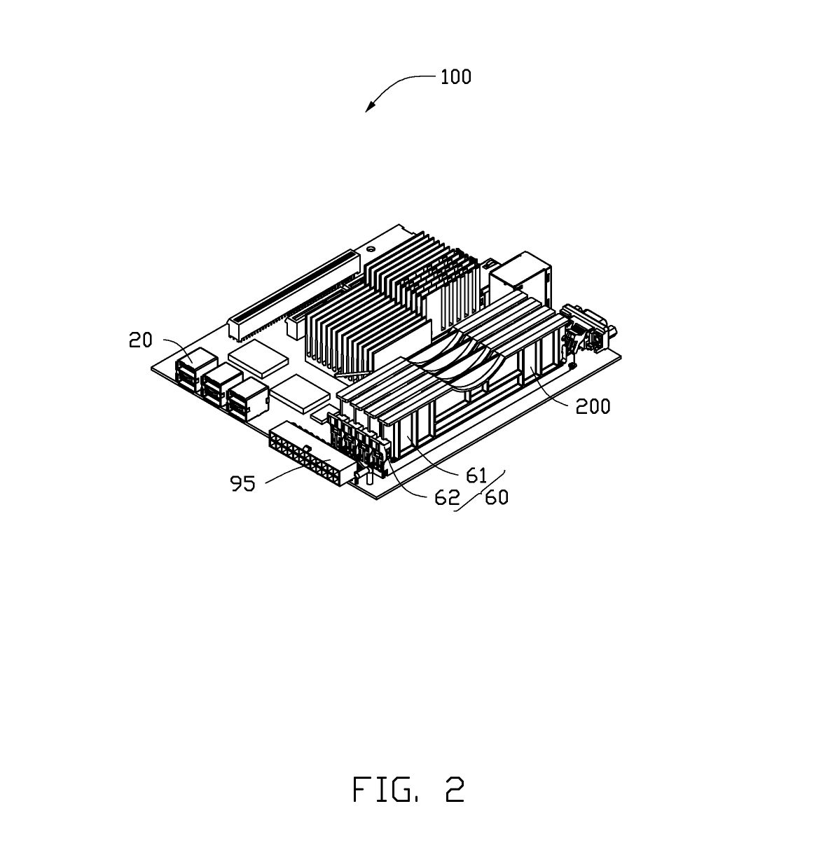

Viewed from the top of the motherboard 100, at least a part of the case 951 projects outside the edge of the circuit board 10, as shown in FIG. 2. With such a construction, the case 951 will take up the least possible space on or above the circuit board 10, which facilitates the minimization of the circuit board 10.

Although the present disclosure has been specifically described on the basis of the exemplary embodiment thereof, the disclosure is not to be construed as being limited thereto. Various changes or modifications may be made to the embodiment without departing from the scope and spirit of the disclosure.

What is claimed is:

1. A power connector for being mounted on a circuit board, the power connector comprising:
a case; and
a pin group comprising a first set of pins, the first set of pins comprising a plurality of first pins, each first pin comprising:
an embedded end protruding from one side of the case;
a median portion angled from the embedded end; and
a distal end angled from the media portion and to be fixed on the circuit board, wherein at least part of the case projects out of a boundary of the circuit board when the power connector is assembled to the circuit board.

2. The power connector as described in claim 1, wherein the side of the case where the embedded end of each first pin protrudes from is vertical, and the distal end of each first pin is perpendicular to the embedded end and parallel to the side.

3. The power connector as described in claim 2, wherein the first pins are arranged at equal intervals.

4. The power connector as described in claim 3, wherein the pin group further comprises a second set of pins, the second set of pins comprises a plurality of second pins protruding from the side and arranged at equal intervals, and the second set of pins is beneath the first set of pins and spaced a certain distance from the first set of pins.

5. The power connector as described in claim 1 further comprising at least two orientation rods, flanking the first set of pins, to be inserted into orientation holes in the circuit board, to locate the power connector on the circuit board.

6. A motherboard, comprising:
a circuit board with a first side, a second side opposite to the first side, a third side between the first side and the second side, and a fourth side opposite to the third side; and
a power connector to be mounted on the circuit board, the power connector comprising:
a case; and
a pin group comprising a first set of pins, the first set of pins comprising a plurality of first pins, each first pin comprising:
an embedded end protruding from one side of the case;
a median portion angled from the embedded end; and
a distal end angled from the media portion and to be fixed on the circuit board, wherein at least part of the case projects out of a boundary of the circuit board when the power connector is assembled to the circuit board.

7. The motherboard as described in claim 6, wherein the side of the case where the embedded end of each first pin protrudes from is vertical, and the distal end of each first pin is perpendicular to the embedded end and parallel to the side.

8. The motherboard as described in claim 7, wherein the first pins are arranged at equal intervals.

9. The motherboard as described in claim 8, wherein the pin group further comprises a second set of pins, the second set of pins comprises a plurality of second pins protruding from the side and arranged at equal intervals, and the second set of pins is beneath the first set of pins and spaced a certain distance from the first set of pins.

10. The motherboard as described in claim 6, wherein the power connector further comprises at least two orientation rods, flanking the first set of pins, to be inserted into orientation holes in the circuit board, to locate the power connector on the circuit board.

11. The motherboard as described in claim 10, wherein the at least two orientation rods are made of plastic materials.

12. The motherboard as described in claim 6, wherein median portions of all the first pins form an incline.

13. The motherboard as described in claim 12 further comprising at least one memory slot arranged beside the power connector, wherein each memory slot comprises a receiving slot to receive a memory and two locking members rotatably connected to two ends of the receiving slot, and when two locking members of a memory slot are pulled back to an unlatching position, a nearer one of the two locking members is capable of resting on the incline.
